(19) United States
(12) Patent Application Publication
(10) Pub. No.: US 2025/0218752 A1
(43) Pub. Date: Jul. 3, 2025

(54) SUBSTRATE PROCESSING APPARATUS, SUBSTATE PROCESSING METHOD USING THE SAME, AND METHOD OF MANUFACTURING SEMICONDUCTOR DEVICE USING THE SAME

(71) Applicant: SAMSUNG ELECTRONICS CO., LTD., Suwon-si (KR)

(72) Inventors: Sejin Oh, Suwon-si (KR); Sang Ki Nam, Suwon-si (KR); Kyung-Sun Kim, Suwon-si (KR); Jin Young Bang, Suwon-si (KR); Dougyong Sung, Suwon-si (KR); Changsoon Lim, Suwon-si (KR); Kangmin Jeon, Suwon-si (KR); Jonghun Pi, Suwon-si (KR)

(21) Appl. No.: 18/763,830

(22) Filed: Jul. 3, 2024

(30) Foreign Application Priority Data
Dec. 29, 2023 (KR) 10-2023-0196276

(51) Int. Cl. H01J 37/32; H01L 21/66; H01L 21/67

(52) U.S. Cl. CPC H01J 37/32972; H01L 21/67253; H01L 22/26; H01J 37/32192; H01J 2237/24507

(57) ABSTRACT

A substrate processing apparatus includes a process chamber having a process space and a port hole, a view port located within the port hole and coupled to the process chamber, a reflector facing the view port and located on an inner wall of the process chamber, a measurement device connected to the view port and measuring plasma in the process space. The measurement device may include a first measurement unit measuring transmittance of the view port reduced by by-products and a second measurement unit measuring electron density in the plasma.

### CROSS-REFERENCE TO RELATED APPLICATIONS

This application claims priority under 35 U.S.C. § 119 to Korean Patent Application No. 10-2023-0196276 filed on Dec. 29, 2023, in the Korean Intellectual Property Office, the entire contents of which are hereby incorporated by reference.

### BACKGROUND

A semiconductor device may be manufactured through various processes. For example, a semiconductor device may be manufactured through a photo process, an etching process, a deposition process, and a plating process on a substrate. Plasma may be used to treat the substrate, such as in an etching process and/or a deposition process. To determine a state of the plasma during the process, light emitted from the plasma may be measured. For example, plasma emission intensity may be measured, and changes in process conditions may be confirmed.

### SUMMARY

In general, in some aspects, the present disclosure is directed toward a substrate processing apparatus that compensates for decreased transmittance due to changes in electron density and by-products, a substrate processing method including the same, and a method of manufacturing a semiconductor device using the same.

According to some implementations, the present disclosure is directed to a substrate processing apparatus that accurately measures an etch end-point using plasma, a substrate processing system including the same, a plasma measurement method using the same, and a substrate processing method using the same.

According to some implementations, the present disclosure is directed to a substrate processing apparatus that includes a process chamber having a process space and a single port hole, a view port located within the port hole and coupled to the process chamber, a reflector facing the view port and located on an inner wall of the process chamber, a measurement device connected to the view port and measuring plasma in the process space, wherein the measurement device includes a first measurement unit measuring transmittance of the view port reduced by by-products and a second measurement unit measuring electron density in the plasma.

According to some implementations, the present disclosure is directed to a substrate processing method that includes preparing a substrate in a substrate processing apparatus, processing the substrate using plasma, and measuring the plasma using a measurement device, wherein the measuring of the plasma includes measuring plasma emission intensity, compensating for electron density in the plasma, and compensating for decreased transmittance due to by-products, and the substrate processing apparatus includes a view port connected to the measurement device, and a reflector facing the view port.

According to some implementations, the present disclosure is directed to a method of manufacturing a semiconductor device that includes forming a mold structure on a substrate, forming a plurality of channel holes penetrating the mold structure using plasma, and measuring the plasma using a measurement device, wherein the measuring of the plasma includes measuring plasma emission intensity, compensating for electron density of the plasma, and compensating for decreased transmittance due to by-products.

### BRIEF DESCRIPTION OF THE DRAWINGS

Example implementations will be more clearly understood from the following detailed description, taken in conjunction with the accompanying drawings.

FIG. 1 is a cross-sectional view illustrating an example of a substrate processing apparatus according to some implementations.

FIG. 2 is an enlarged view of an example of a portion P1 of a substrate processing apparatus according to some implementations.

FIG. 3 is an enlarged view for explaining an example of a portion P2 of a substrate processing apparatus according to some implementations.

FIG. 4 is a flowchart of an example of a substrate processing method according to some implementations.

FIGS. 5 to 9 are diagrams showing an example of a substrate processing method according to some implementations.

FIGS. 10 to 14 are diagrams showing an example of a method of manufacturing a semiconductor device using a substrate processing method according to some implementations.

### DETAILED DESCRIPTION

Hereinafter, example implementations will be explained in detail with reference to the accompanying drawings. The same reference signs may refer to the same elements throughout the specification.

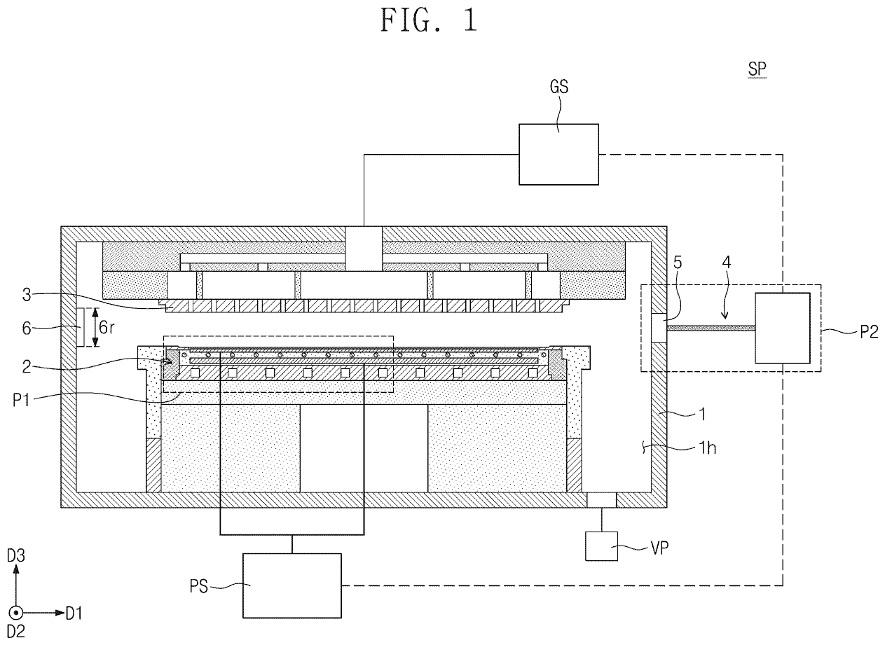

FIG. 1 is a cross-sectional view illustrating an example of a substrate processing apparatus according to some implementations. In FIG. 1, a substrate processing apparatus SP may be provided. The substrate processing apparatus SP may process a substrate using plasma. For example, the substrate processing apparatus SP may perform an etching process and/or a deposition process on the substrate. The term substrate used in present disclosure may refer to a silicon (Si) wafer, but is not limited thereto.

The substrate processing apparatus SP may generate plasma. The substrate processing apparatus SP may generate plasma in various ways. For example, the substrate processing apparatus SP may be equipment having a capacitively coupled plasmas (CCP) and/or inductively coupled plasmas (ICP) structure. The substrate processing apparatus SP may include a process chamber 1, an electrostatic chuck 2, a shower head 3, a measurement device 4, a view port 5, a reflector 6, a power generator PS, and a vacuum pump VP and a gas supplier GS.

The process chamber 1 may have a process space 1h therein. A substrate may be placed in the process space 1h, and may be a space for processing the substrate. The process space 1h may be separated from the external space by the process chamber 1. During substrate processing, the process space 1h may be substantially vacuumed. For example, the process chamber 1 may have a cylindrical shape, but is not limited thereto. The process chamber 1 may include a material with excellent heat resistance and corrosion resistance. For example, the process chamber 1 may include, but is not limited to, yttrium oxide (Y₂O₃) and yttrium fluoride (YF₃).

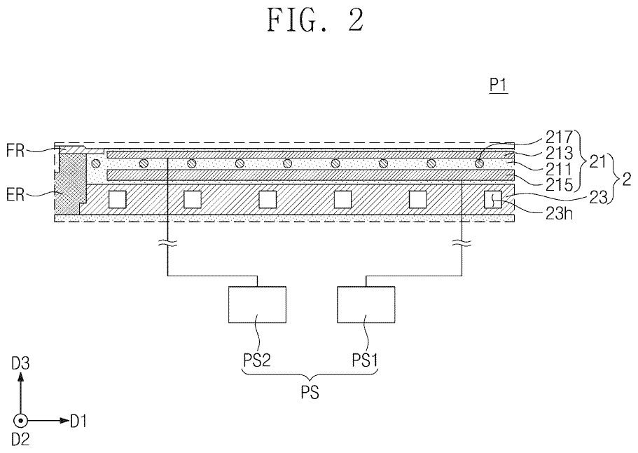

The electrostatic chuck 2 may be located within process chamber 1. For example, the electrostatic chuck 2 may be located at a center of the process space 1h. The electrostatic chuck 2 may support and/or secure the substrate. With the substrate placed on the electrostatic chuck 2, processing of the substrate may proceed. Hereinafter, a detailed description of the electrostatic chuck 2 will be provided with reference to FIG. 2.

The shower head 3 may be positioned within the process chamber 1 on the electrostatic chuck 2. For example, the shower head 3 may be located at an upper portion of the process space 1h. The shower head 3 may be spaced apart from the electrostatic chuck 2 in a vertical direction. The shower head 3 may have a plurality of gas holes. The plurality of gas holes may be spaced apart from each other in a horizontal direction.

In some implementations, a first direction D1 and a second direction D2 may intersect a third direction D3. Additionally, the first direction D1 and the second direction D2 may intersect each other. The third direction D3 may correspond to the vertical direction. The first direction D1 and the second direction D2 may correspond to the horizontal direction.

The gas supplier GS may be connected to the shower head 3. The gas supplier GS may supply process gas. In some implementations, the gas supplier GS may include a gas tank, a compressor, and a valve. For example, the process gas may move from the gas supplier GS to the process space 1h of the process chamber 1 through the shower head 3. Due to the plurality of gas holes in the shower head 3, the process gas may be uniformly sprayed into the process space 1h.

The power generator PS may be located outside the process chamber 1. For example, the power generator PS may not be located within the process space 1h. The power generator PS may be connected to the electrostatic chuck 2. The power generator PS may apply power to the electrostatic chuck 2 to fix the substrate or generate and/or control plasma. Hereinafter, a detailed description of the power generator PS will be provided with reference to FIG. 2.

The vacuum pump VP may be connected to the process space 1h through a lower portion of the process chamber 1. The vacuum pump VP may make the process space 1h of the process chamber 1 substantially vacuum. Additionally, the vacuum pump VP may maintain the process space 1h of the process chamber 1 at a constant pressure. To this end, the vacuum pump VP may include a valve or the like. Using the vacuum pump VP, the substrate may be processed under low pressure.

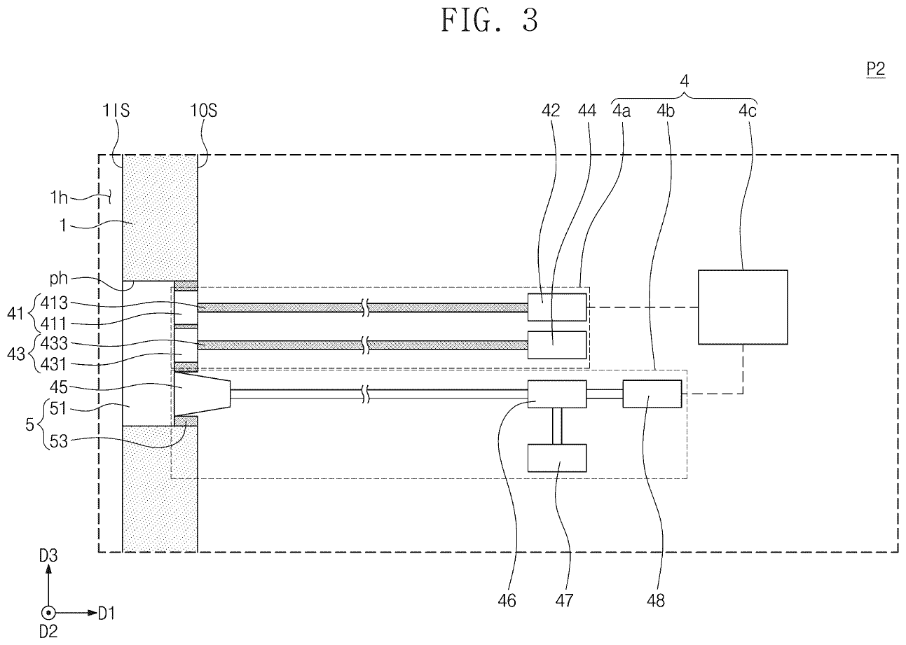

The view port 5 may be located on one side of the process chamber 1. The view port 5 may be located at a higher level (or height) than the electrostatic chuck 2. The view port 5 may be coupled to the process chamber 1 and may be connected to the measurement device 4. For example, the measurement device 4 may be located outside the process chamber 1 and may be connected to the view port 5. The measurement device 4 may observe the inside of the substrate processing apparatus SP. For example, the measurement device 4 may measure plasma formed in the process space 1h of the substrate processing apparatus SP. The measurement device 4 may be connected to the gas supplier GS and the power generator PS and may exchange electrical signals. Hereinafter, a detailed description of the view port 5 and the measurement device 4 will be provided in FIG. 3.

The reflector 6 may be located on an inner wall of the process chamber 1. The reflector 6 may face the view port 5. The reflector 6 may be positioned at the same level as the view port 5. For example, the reflector 6 and the view port 5 may be located at a higher level than the electrostatic chuck 2 and may be located at both ends of the process chamber 1. Accordingly, light and/or signals emitted from the view port 5 may be reflected on the reflector 6 across the process space 1h of the process chamber 1 and may enter the view port 5 again.

For example, the reflector 6 may include silicon (Si)-based, yttrium oxide (Y₂O₃), yttrium fluoride (YF₃), and combinations thereof. In detail, the reflector 6 may be silicon (Si) coated with yttrium oxide (Y₂O₃) or yttrium fluoride (YF₃). A diameter 6r of the reflector 6 may be larger than a diameter of the light transmission device 41 and 43 (e.g., see FIG. 3) of the measurement device 4, which will be described later. For example, a diameter 6r of the reflector 6 may be about 1 mm to about 2 mm. The reflector 6 may have a circular plate shape, but is not limited thereto.

FIG. 2 is an enlarged view showing a portion P1 of a substrate processing apparatus according to some implementations. In FIG. 2, the electrostatic chuck 2 may include an upper chuck 21 and a cooling plate 23. The upper chuck 21 may include a chuck body 211, a plasma electrode 215, a chuck electrode 213, and a heater 217. Additionally, the power generator PS may include a first power generator PS1 and a second power generator PS2.

The chuck body 211 may have a cylindrical shape. The substrate may be placed on the upper surface of the chuck body 211. A focus ring FR and/or an edge ring ER may be provided on a side surface of the chuck body 211. The focus ring FR may be located on the edge ring ER. The focus ring FR and/or edge ring ER may surround the chuck body 211. For example, the chuck body 211 may include ceramic, but is not limited thereto.

The plasma electrode 215 may be located within the chuck body 211. The plasma electrode 215 may be disposed on a lower portion of the chuck body 211. The plasma electrode 215 may have a shape of a disk. An electrical power may be applied to the plasma electrode 215. For example, the first power generator PS1 may be connected to the plasma electrode 215. The first power generator PS1 may apply RF power to the plasma electrode 215. Plasma may be generated and/or controlled on the chuck body 211 by RF power applied to the plasma electrode 215. For example, the plasma electrode 215 may include a conductive material such as aluminum (Al).

The chuck electrode 213 may be located within the chuck body 211 and on the plasma electrode 215. For example, the chuck electrode 213 may be disposed on an upper portion of the chuck body 211. The chuck electrode 213 may be connected to the second power generator PS2. The second power generator PS2 may apply DC power to the chuck electrode 213. The substrate positioned on the chuck body 211 may be fixed to the electrostatic chuck 2 by the DC power applied to the chuck electrode 213. For example, the chuck electrode 213 may include a conductive material such as aluminum (Al).

The heater 217 may be located within the chuck body 211. The heater 217 may be disposed between the chuck electrode 213 and the plasma electrode 215. The heater 217 may include a heating wire. A plurality of heating wires of the heater 217 may be provided. For example, the heating wire of the heater 217 may have a concentric circle shape, but is not limited thereto. The heater 217 may radiate heat to the surroundings. Accordingly, a temperature of the chuck body 211 increases, making it possible to control the temperature of the substrate on the chuck body 211.

The cooling plate 23 may be located below the upper chuck 21. The cooling plate 23 may be in contact with the chuck body 211 of the upper chuck 21. The cooling plate 23 may have a plurality of cooling holes 23h. Coolant may flow through the plurality of cooling holes 23h. The coolant may absorb heat of the chuck body 211 in contact with the cooling plate 23. For example, the heater 217 may increase the temperature of the chuck body 211, and the coolant flowing in the plurality of cooling holes 23h may lower the temperature of the chuck body 211. Accordingly, the temperature of the substrate positioned on the chuck body 211 may be controlled.

FIG. 3 is an enlarged view of a portion P2 of a substrate processing apparatus according to some implementations. In FIG. 3, the process chamber 1 may have a port hole ph, and the view port 5 may be located within the port hole ph. The view port 5 may be coupled with the process chamber. Within the port hole ph, an O-ring may be provided between the view port 5 and the process chamber 1. The O-ring may prevent air from passing between the view port 5 and the process chamber 1. Accordingly, the process space 1h of the process chamber 1 may be sealed from the outside.

The view port 5 may include a window 51 and a guide unit 53. The window 51 and the guide unit 53 may be in contact with each other. The window 51 may be exposed to the process space 1h of the process chamber 1. For example, the window 51 may be adjacent to an inner wall 1IS of the process chamber 1, and the guide unit 53 may be adjacent to an outer wall 1OS of the process chamber 1.

The window 51 may transmit light and/or electromagnetic waves within the process space 1h of the process chamber 1. For example, the window 51 may be made of a transparent or translucent material. The window 51 may include quartz. When viewed in the first direction D1, the window 51 may have a circular shape, but is not limited thereto. For example, the window 51 may have a polygonal shape such as a triangle, square, or oval.

The guide unit 53 may be combined with a portion of the measurement device 4. In some implementations, the guide unit 53 may be a member for coupling and fixing the measurement device 4 to the view port 5. For example, light transmission devices 41 and 43 and an antenna 45 of the measurement device 4, which will be described later, may be combined with the guide unit 53. According to some implementations, the guide unit 53 may be omitted.

The measurement device 4 may include a first measurement unit 4a, a second measurement unit 4b, and a controller 4c. The first measurement unit 4a may include the first and second light transmission devices 41 and 43, a spectroscope 42, and an external light source 44. The second measurement unit 4b may include the antenna 45, a duplexer 46, a transmitter 47, and a receiver 48.

Each of the first and second optical transmission devices 41 and 43 of the first measurement unit 4a may include a collimator and an optical cable. For example, the first optical transmission device 41 may include a first collimator 411 and a first optical cable 413, and the second optical transmission device 43 may include a second collimator 431 and a second optical cable 433. Each of the first and second collimators 411 and 431 may be coupled to the guide portion 53 and fixed to face the window 51. The first and second collimators 411 and 431 may be spaced apart from each other in the third direction D3, but are not limited thereto. For example, the first and second collimators 411 and 431 may be arranged to be spaced apart from each other in the second direction D2. The first optical cable 413 may be connected to the spectroscope 42. The second optical cable 433 may be connected to the external light source 44. For example, the first and second optical cables 413 and 433 may include optical fibers.

Incident light through the first collimator 411 may reach the spectrometer 42 through the first optical cable 413. For example, the light generated in the process space 1h may reach the spectrometer 42 through the first light transmission device 41. The spectrometer 42 may measure the light generated in the process space 1h depending on wavelength and intensity thereof. For example, the spectrometer 42 may measure wavelengths from ultraviolet rays to near-infrared rays. A measurement wavelength range of the spectrometer 42 may be from about 200 nm to about 1000 nm.

As the external light source 44 is connected to the second optical cable 433, light generated from the external light source 44 may move to the process space 1h through the second collimator 431. In some implementations, the light generated from the external light source 44 may move to the process space 1h of the process chamber 1 through the second light transmission device 43. For example, the external light source 44 may include a xenon flash lamp.

A size of the antenna 45 of the second measurement unit 4b may increase as it approaches the window 51. Additionally, the antenna 45 may include a metallic material. For example, the antenna 45 may be a horn antenna for inducing electromagnetic waves. The antenna 45 may be connected to the duplexer 46. The duplexer 46 may transmit and receive a transmission signal and a reception signal simultaneously. That is, the duplexer 46 may be a device that enables two-way communication. Accordingly, the second measurement unit 4b may transmit and receive electromagnetic waves with one antenna 45.

Each of the receiver 48 and the transmitter 47 may be connected to the duplexer 46. The transmitter 47 may generate electromagnetic waves. For example, the transmitter 47 may generate microwaves. A frequency of the microwave may be about 1 GHz to about 100 GHZ, and more preferably about 26 GHz. The receiver 48 may receive electromagnetic waves and may measure phase and frequency of the electromagnetic waves. For example, the receiver 48 may compare a phase and a frequency of the electromagnetic wave generated by the transmitter 47 to those of the electromagnetic wave received.

The controller 4c may be connected to the spectrometer 42 of the first measurement unit 4a and the receiver 48 of the second measurement unit 4b. Information about the light measured by the spectrometer 42 may be transmitted to the controller 4c. Information about the electromagnetic waves measured by the receiver 48 may be transmitted to the controller 4c. The controller 4c may detect changes in the process space 1h of the process chamber 1 by analyzing information about the light and/or the electromagnetic waves. Additionally, the controller 4c may be connected to the gas supplier GS and the power generator PS of FIG. 1 to exchange electrical signals. Accordingly, the controller 4c may control the gas supplier GS and the power generator PS depending on changes in the process space 1h.

In FIGS. 1 and 3, the substrate processing apparatus SP may include the duplexer 46, and may receive and transmit electromagnetic waves using one antenna 45. Additionally, the reflector 6 may be provided at a position opposite to the view port 5, and the light and/or the electromagnetic waves may be sent and received back to one view port 5. For example, as the plurality of port holes are not required to send and receive the light and/or the electromagnetic waves, it may be easy to design of the substrate processing apparatus SP.

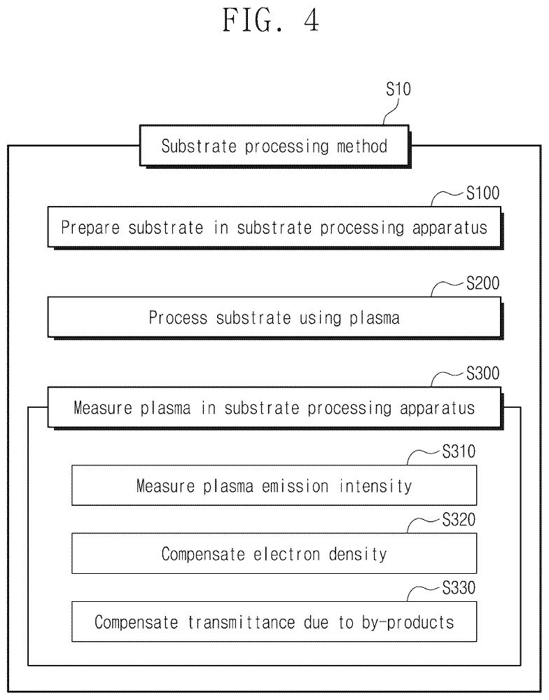

FIG. 4 is a flowchart showing an example of a substrate processing method according to some implementations. In FIG. 4, a substrate processing method of S10 may be provided. The substrate processing method of S10 may be a method of processing a substrate using the substrate processing apparatus SP described with reference to FIGS. 1 to 3. The substrate processing method of S10 may include preparing a substrate in a substrate processing apparatus in S100, processing the substrate using plasma in S200, and measuring the plasma in the substrate processing apparatus in S300. Additionally, the processing of the substrate using plasma in S200 and the measuring of the plasma in the substrate processing apparatus in S300 may be performed simultaneously. For example, the measuring of the plasma in the substrate processing apparatus in S300 may correspond to monitoring the substrate in the substrate processing step in S200.

The measuring of the plasma in the substrate processing apparatus in S300 may include measuring the plasma emission intensity in S310, compensating for electron density in S320, and compensating for reduced transmittance due to by-products in S330.

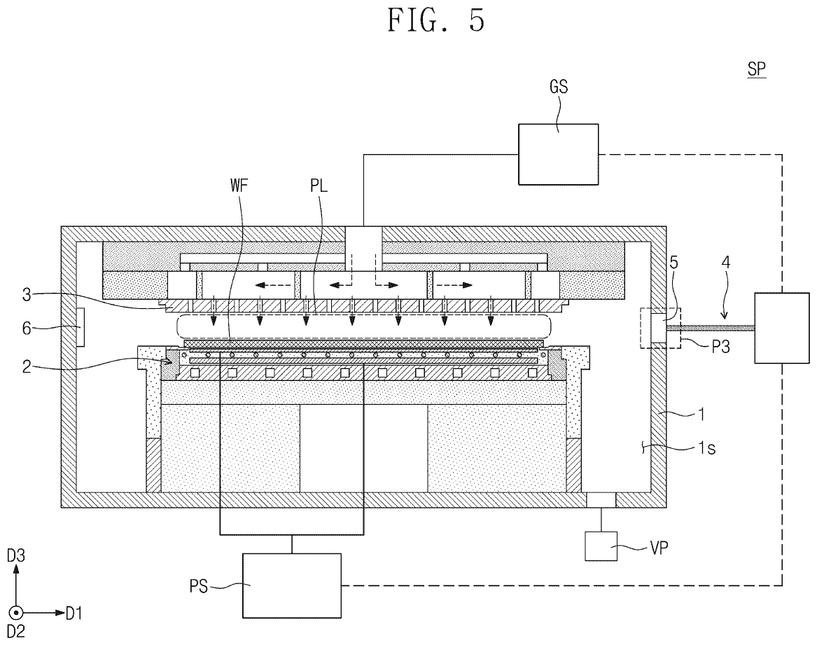

Hereinafter, the substrate processing method of S10 of FIG. 4 will be described in detail with reference to FIGS. 5 to 9.

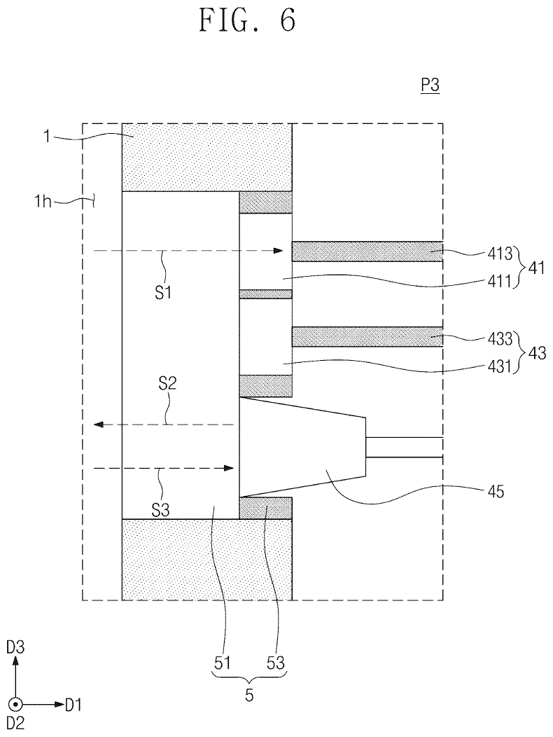

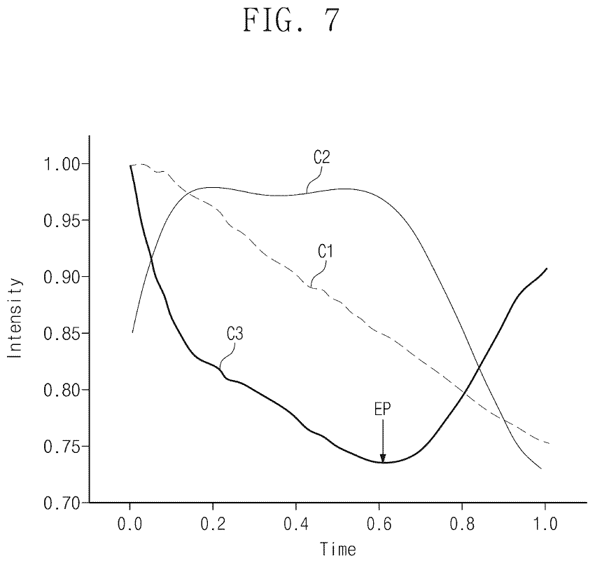

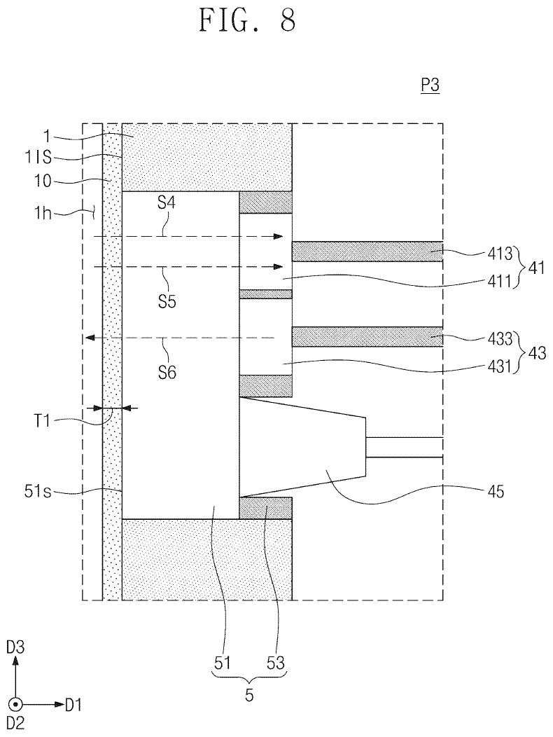

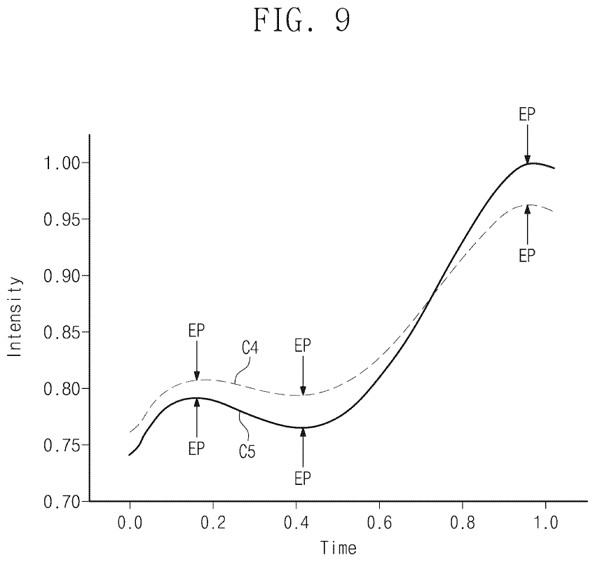

FIGS. 5 to 9 are diagrams showing an example of a substrate processing method according to some implementations. FIG. 5 is a cross-sectional view showing a substrate processing apparatus during substrate processing, FIGS. 6 and 8 are enlarged cross-sectional views of an example of a region ‘P3’ region of FIG. 5 according to some implementations, and FIGS. 7 and 9 are graphs showing data obtained by a substrate processing method according to some implementations.

In FIGS. 4 and 5, the preparing of the substrate in the substrate processing apparatus in S100 may include placing the substrate W on the electrostatic chuck 2 and fixing the substrate W on the electrostatic chuck 2. For example, when the substrate W is positioned on the electrostatic chuck 2, the second power generator PS2 may apply DC voltage to the chuck electrode 213 of the electrostatic chuck 2, as described with reference to FIG. 2. Accordingly, the substrate W may be fixed to the electrostatic chuck 2. Thereafter, the process space 1h of the process chamber 1 may be maintained in a vacuum state using the vacuum pump VP.

The processing of the substrate using plasma in S200 may include supplying process gas to the process space 1h, supplying RF power to the electrostatic chuck 2, forming plasma PL, and etching the substrate W.

In detail, the process gas may move from the gas supplier GS to the process space 1h through the shower head 3. The shower head 3 may have a plurality of gas holes to uniformly supply the process gas.

As described with reference to FIG. 2, the first power generator PS1 may apply RF power to the plasma electrode 215. Accordingly, an electric field may be formed within the process space 1h. The process gas within the process space 1h may be converted into plasma PL due to the electric field. For example, the plasma PL may be formed between the substrate W and the shower head 3. Thereafter, the plasma PL may etch at least a portion of the substrate W. By-products generated while etching the substrate W may be re-deposited on the substrate W or the process chamber 1.

In FIGS. 4, 5, and 6, the measuring of the plasma emission intensity in S310 may include measuring incident light S1 emitted from the plasma PL. For example, the plasma PL may include ionized particles, and the ionized particles may emit light as they become stabilized. The incident light S1 may enter the first collimator 411 and move to the spectrometer 42 of FIG. 3 through the first optical cable 413. In some implementations, the intensity of incident light S1 emitted from the plasma PL may be referred to as plasma emission intensity. The plasma emission intensity may be described by [Equation 1].

I∝VC×(σVₑ)×Dₑ×D_{c} [Equation 1]

‘I’ corresponds to a plasma emission intensity, ‘VC’ represents a clogging effect, ‘σ’ is an excitation cross-section, and ‘Vₑ’ is an electron velocity. Additionally, ‘Dₑ’ is an electron density and ‘D_{c}’ corresponds to a chemical species density. As the excitation cross-section and the electron velocity are values determined depending on process conditions, the excitation cross-section and the electron velocity may be constants. Accordingly, the plasma emission intensity may be determined by the clogging effect, electron density, and chemical species density.

The compensating of the electron density in S320 may include measuring the change in electron density and excluding the change in electron density from the emission intensity of the plasma PL.

In some implementations, interferometry may be used to measure changes in electron density. For example, the higher the electron density in the plasma PL, the faster the speed of electromagnetic waves. Accordingly, the phase and/or frequency of the electromagnetic waves may be variously changed. For example, the change in electron density may be measured using an interference of the electromagnetic wave before passing through the plasma PL and the electromagnetic wave after passing through the plasma PL.

For example, the first electromagnetic wave S2 may be transmitted from the transmitter 47 in FIG. 3. The second electromagnetic wave S3 may be received by the receiver 48 of FIG. 3. The first electromagnetic wave S2 may be emitted from the antenna 45, pass through the plasma PL, and be reflected by the reflector 6. The first electromagnetic wave S2 reflected by the reflector 6 may pass through the plasma PL again and enter the antenna 45. For example, the second electromagnetic wave S3 may be substantially the same as the first electromagnetic wave S2 passed through the plasma PL and reflected by the reflector 6. In another example, the second electromagnetic wave S3 may be a first electromagnetic wave S2 whose phase and/or frequency changes depending on the electron density of the plasma PL. As a result, the change in electron density may be measured using the interference of the first electromagnetic wave S2 and the second electromagnetic wave S3.

Excluding changes in electron density from the plasma emission intensity may represent changes in chemical species density. According to [Equation 1], as the plasma emission intensity is proportional to the electron density and the chemical species density, the chemical species density is proportional to the plasma emission intensity and inversely proportional to the electron density. Accordingly, the change in chemical species density may be calculated by dividing the plasma emission intensity by the change in electron density.

In FIG. 7, a horizontal axis of a graph may indicate relative time. For example, 0 on the horizontal axis may be the time when substrate processing begins, and 1 on the horizontal axis may be the time when substrate processing ends. A vertical axis of the graph may indicate relative intensity. For example, 1 on the vertical axis may be the largest intensity, and 0.7 on the vertical axis may be the smallest intensity.

A first line C1 may correspond to an plasma emission intensity. The plasma emission intensity may continue to decrease over time.

A second line C2 may correspond to electron density. The electron density may increase from 0 to 0.2 on the horizontal axis and may have a substantially constant value from 0.2 to 0.6 on the horizontal axis. After 0.6 on the horizontal axis, the electron density may rapidly decrease.

A third line C3 may be a value obtained by compensating the electron density for the plasma emission intensity. For example, as the plasma emission intensity is divided by the electron density, the third line C3 may correspond to the chemical species density. The chemical species density may continuously decrease from 0 to 0.6 on the horizontal axis and then increase rapidly from 0.6 on the horizontal axis.

In the etching process, the changes in the chemical species density may indicate that materials contained in the etched layers are different. For example, the changes in the chemical species density may mean that an interface between layers containing different materials is being etched. In other words, 0.6 on the horizontal axis may correspond to an etch end-point EP.

In FIGS. 4, 5, and 8, as the process of processing the substrate W is repeated, by-products may be generated in the process space 1h. Most of the by-products may be discharged to the vacuum pump VP, but some of the by-products may remain in the process space 1h. In some implementations, the by-products may be deposited on the inner wall 1IS of the process chamber 1. For example, the by-product layer 10 may be formed in a form of a layer on the inner wall 1IS of the process chamber 1, and the by-product layer 10 may also be formed on the surface 51s of the window 51. Accordingly, the amount of light passing through the window 51 may decrease. That is, a transmittance of the view port 5 may be reduced by the by-product, which may correspond to the clogging effect described above.

The by-product layer 10 may have a thickness T1 in the first direction D1, and the thickness T1 of the by-product layer 10 may be variously changed depending on the operation time of the substrate processing apparatus SP. For example, the by-product layer 10 may not be present immediately after the substrate processing apparatus SP is cleaned. As the process of processing the substrate W progresses, the by-product layer 10 may be formed. As an operation time of the substrate processing apparatus SP increases, the thickness T1 of the by-product layer 10 may increase. That is, since the thickness T1 of the by-product layer 10 is variously changed depending on the operation time of the substrate processing apparatus SP, the transmittance of the view port 5 may be variously changed. Accordingly, to accurately measure the plasma emission intensity, it may be necessary to compensate for the transmittance decreased by the by-product in S330.

The compensating for the transmittance decreased by the by-product in S330 may include blinking the external light source and comparing the plasma emission intensity. The external light source 44 of FIG. 3 may be connected to the second optical transmission device 43, and external light S6 may be emitted to the second collimator 431 through the second optical cable 433.

When there is no external light S6, the first incident light S4 may reach the view port 5. In this case, light may be emitted only from the plasma PL. For example, the first incident light S4 may correspond to the light emitted from the plasma PL that does not include the external light S6.

When there is external light S6, second incident light S5 may reach the view port 5. The external light S6 may pass through the window 51 and the by-product layer 10, cross the substrate W, and reach the reflector 6. After being reflected by the reflector 6, the external light S6 may reach the view port 5 together with the light emitted from the plasma PL. For example, the second incident light S5 may be the light emitted from the plasma PL including the external light S6. Accordingly, an intensity of the second incident light S5 may be greater than an intensity of the first incident light S4.

As a thickness of the by-product layer 10 increases, a transmittance of external light S6 may decrease. A ratio of the external light S6 to the second incident light S5 may be reduced. Accordingly, a difference between the first incident light S4 and the second incident light S5 may be reduced. Conversely, as the thickness of the by-product layer 10 decreases, the transmittance of external light S6 may increase. As the ratio of the external light S6 to the second incident light S5 increases, the difference between the first incident light S4 and the second incident light S5 may increase.

As the process of processing the substrate W is repeated, the thickness T1 of the by-product layer 10 may increase, and the decrease in transmittance due to the by-products may be compensated as the difference between the first incident light S4 and the second incident light S5 decreases. In some implementations, the clogging effect may be compensated by comparing the difference between the plasma emission intensity in the absence of external light S6 and the plasma emission intensity in the presence of external light S6.

In FIG. 9, a horizontal axis of a graph may indicate relative time. For example, 0 on the horizontal axis may be the time when substrate processing begins, and 1 on the horizontal axis may be the time when substrate processing ends. A vertical axis of the graph may indicate relative intensity. For example, 1 on the vertical axis may be the largest intensity, and 0.7 on the vertical axis may be the smallest intensity.

A fourth line C4 may correspond to a plasma emission intensity before compensating for the decrease in transmittance due to the by-products. A fifth line C5 may correspond to a plasma emission intensity that compensates for the decrease in transmittance due to the by-products.

When comparing the fourth line C4 and the fifth line C5, the minimum value of the fourth line C4 may be greater than the minimum value of the fifth line C5. The maximum value of the fourth line C4 may be less than the maximum value of the fifth line C5. As a rate of change of the fourth line C4 is less than a rate of change of the fifth line C5, a change in slope of the fourth line C4 may be smaller than a change in slope of the fifth line C5. An etch end-point EP of the fifth line C5 may be more easily confirmed than an etch end-point EP of the fourth line. Accordingly, by compensating for the decrease in transmittance due to the by-products, accuracy of the etch end-point EP may be improved.

The substrate processing method of S10 according to some implementations may include the measuring of the plasma in S300, and the measuring of the plasma in S300 may include the measuring of the plasma emission intensity in S310, the compensating for the electron density in S320, and the compensating for the transmittance decreased by the by-products in S330. This may allow the change in chemical species density to be calculated by excluding the electron density and clogging effects from the plasma emission intensity. The chemical species density may change at the interface of layers containing different materials during the etching process. Accordingly, the substrate processing method of S10 may provide a precise etch end-point EP.

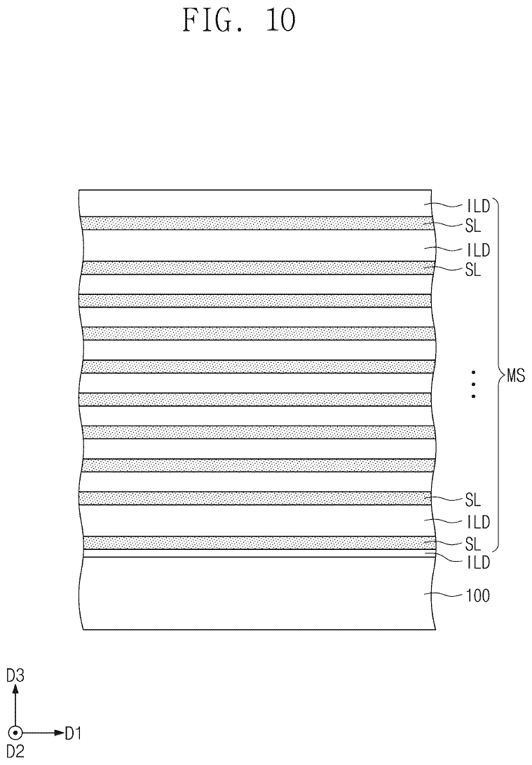

FIGS. 10 to 14 are diagrams showing an example of a method of manufacturing a semiconductor device using a substrate processing method according to some implementations. In FIG. 10, a semiconductor device may be a semiconductor memory device, and specifically, may be a three-dimensional semiconductor memory device. Insulating layers ILD and sacrificial layers SL may be formed on the substrate 100. The insulating layers ILD and the sacrificial layers SL may be alternately stacked in a third direction D3 perpendicular to an upper surface of the substrate 100 to form a mold structure MS. For example, the insulating layers ILD and sacrificial layers SL may be formed through a chemical vapor deposition process.

The sacrificial layers SL of the mold structure MS may include a material that has etch selectivity with respect to the insulating layers ILD. For example, the sacrificial layers SL may include silicon nitride, and the insulating layers ILD may include silicon oxide.

The lowermost of the insulating layers ILD may be formed between the lowermost of the sacrificial layers SL and the substrate 100, and may have a smaller thickness in the third direction D3 than the other of the insulating layers ILD. For example, the lowermost one of the insulating layers ILD may be formed through a thermal oxidation process following a deposition process.

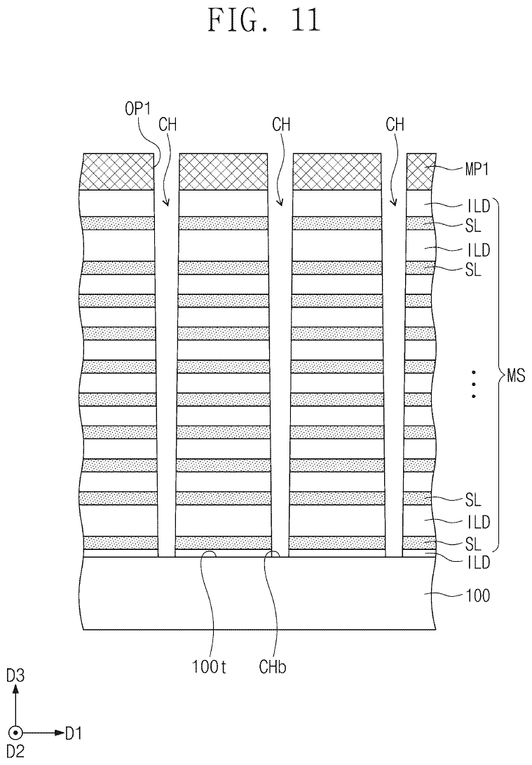

In FIG. 11, channel holes CH may be formed penetrating the insulating layers ILD and sacrificial layers SL of the mold structure MS. The channel holes CH may expose sidewalls of the insulating layers ILD and the sacrificial layers SL. The channel holes CH may expose a portion of an upper surface 100t of the substrate 100. A width of each channel hole CH may become smaller as it approaches the substrate 100, but is not limited thereto.

Forming the channel holes CH may include forming a first mask pattern MP1 having a first opening OP1 on the mold structure MS, performing a plasma etching process using the first mask pattern MP1, and measuring the plasma of the plasma etching process. A width of the first opening OP1 may be substantially the same as a width of each of the channel holes CH.

The measuring of the plasma may be substantially the same as the measuring of the plasma in S300 in the substrate processing apparatus described with reference to FIGS. 4 to 9. For example, the measuring of the plasma may include measuring the plasma emission intensity in S310, compensating for transmittance decreased by electron density and the by-products in S320 and in S330. Accordingly, an etch end-point may be accurately measured at an interface between the lowermost one of the insulating layers ILD and the substrate 100. For example, the upper surface 100t of the substrate 100 may not be overetched. The upper surface 100t of the substrate 100 and bottom surfaces CHb of the channel holes CH may be coplanar.

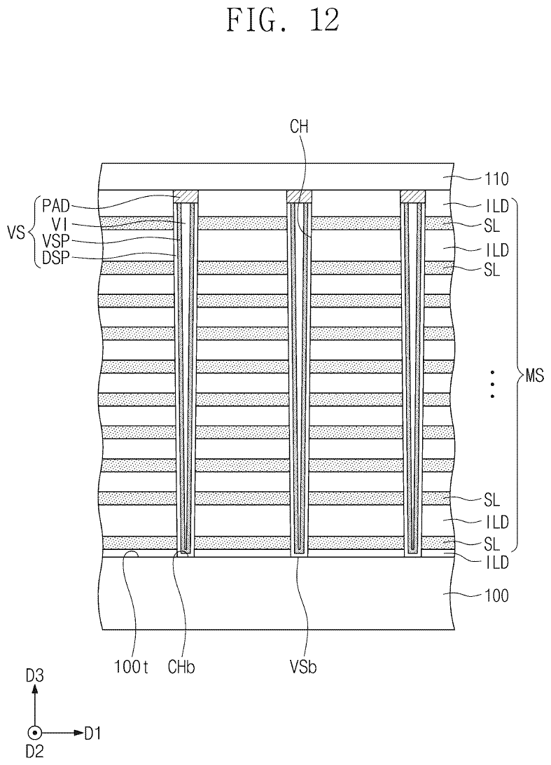

In FIG. 12, vertical structures VS including a data storage pattern DSP, a vertical semiconductor pattern VSP, a vertical insulating pattern VI, and a conductive pad PAD may be formed inside the channel holes CH. Lower surfaces VSb of the vertical structures VS may be coplanar with the upper surface 100t of the substrate 100 and the bottom surfaces CHb of the channel holes CH.

The data storage pattern DSP may be formed on sidewalls of the channel holes CH. The vertical semiconductor pattern VSP having a uniform thickness may be formed on the data storage pattern DSP. The data storage pattern DSP and vertical semiconductor pattern VSP may be formed by a chemical vapor deposition or atomic layer deposition process. For example, the data storage pattern DSP and vertical semiconductor pattern VSP may be in the form of a pipe with a closed bottom or a macaroni shape.

The vertical insulating pattern VI may fill a space surrounded by the data storage pattern DSP and the vertical semiconductor pattern VSP. The vertical insulating pattern VI may be formed by filling an inner space of each of the channel holes CH surrounded by the vertical semiconductor pattern VSP with an insulating material and performing a planarization process to expose an upper surface of the mold structure MS.

Accordingly, a conductive pad PAD may be formed on the data storage pattern DSP, the vertical semiconductor pattern VSP, and the vertical insulating pattern VI. The conductive pad PAD may be formed by recessing upper portions of the data storage pattern DSP, vertical semiconductor pattern VSP, and vertical insulating pattern VI and filling the recessed region with a doped semiconductor material or conductive material.

An upper insulating layer 110 may be formed on the uppermost one of the insulating layers ILD and the conductive pad PAD. The upper insulating layer 110 may cover the mold structure MS and the conductive pad PAD. For example, the upper insulating layer 110 may include any one of silicon nitride, silicon oxide, and silicon oxynitride.

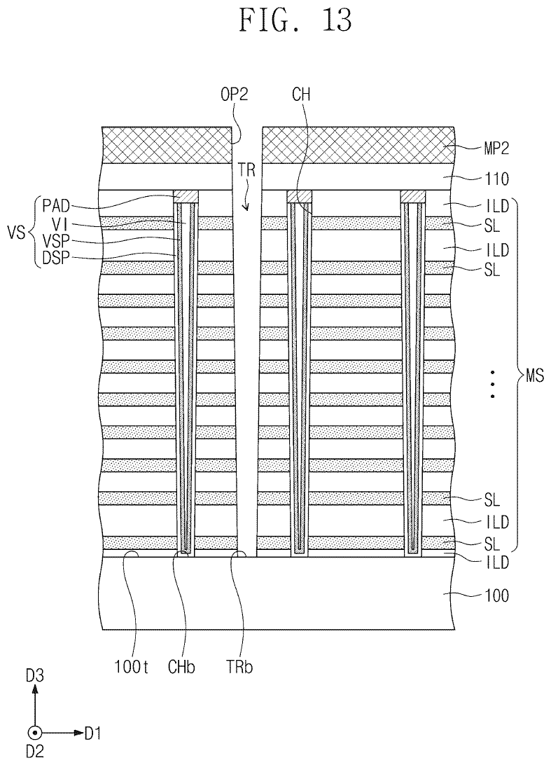

In FIG. 13, a separation trench TR may be formed penetrating the upper insulating layer 110 and the mold structure MS. The forming of the separation trench TR may include forming a second mask pattern MP2 having a second opening OP2 on the upper insulating layer 110, plasma etching using the second mask pattern MP2, and measuring plasma of the plasma etching process. The measuring of the plasma may be substantially the same as the measuring of the plasma of S300 in the substrate processing apparatus described with reference to FIGS. 4 to 9. As described with reference to FIG. 11, an etch end-point may be accurately measured at an interface between the bottom of the insulating layers ILD and the substrate 100. The upper surface 100t of the substrate 100 may not be overetched. The bottom surface TRb of the separation trench TR may be coplanar with the upper surface 100t of the substrate 100 and the bottom surfaces CHb of the channel holes CH.

The separation trench TR may be spaced apart from the vertical structures VS in the first direction D1. The separation trench TR may expose a portion of the upper surface 100t of the substrate 100. Additionally, the separation trench TR may expose sidewalls of the insulating layers ILD and the sacrificial layers SL.

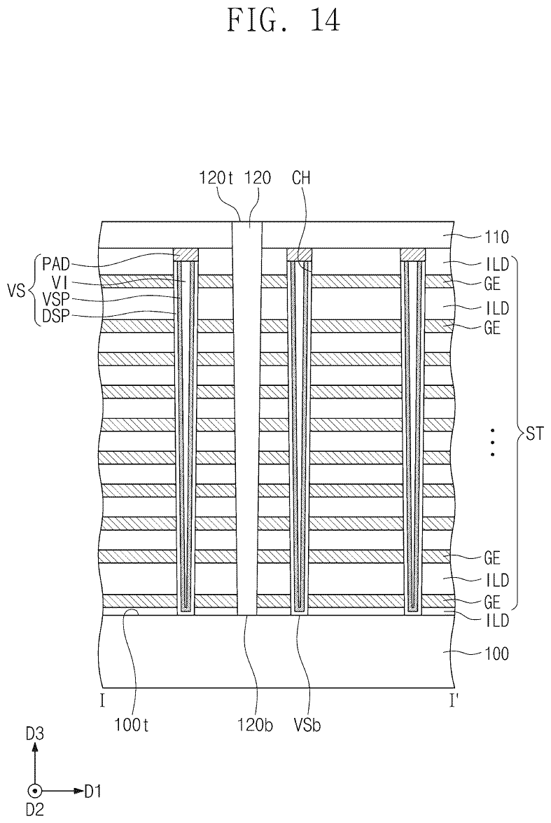

In FIG. 14, the sacrificial layers SL exposed by the separation trench TR may be selectively removed. Selective removal of the sacrificial layers SL may be performed through a wet etching process using an etching solution. For example, the sacrificial layers SL may be selectively removed using an etching solution containing hydrofluoric acid or phosphoric acid.

Gate electrodes GE may be formed in a space where the sacrificial layers SL have been removed. Forming the gate electrodes GE may include forming a conductive layer that fills the space where the sacrificial layers SL were removed and the isolation trench TR, and removing the conductive layer inside the separation trench TR. Accordingly, the conductive layer may be formed with gate electrodes GE separated from each other. As the gate electrodes GE are formed, a stacked structure ST may be formed including the gate electrodes GE and insulating layers ILD alternately stacked in the third direction D3 perpendicular to the upper surface 100t of the substrate 100.

Thereafter, a separation structure 120 may be formed in the separation trench TR. Forming the separation structure 120 may include filling the separation trench TR with an insulating material and performing a planarization process on the insulating material to expose the upper insulating layer 110. A lower surface 120b of the separation structure 120 may be coplanar with the lower surfaces VSb of the vertical structures VS and the upper surface 100t of the substrate 100. Additionally, an upper surface 120t of the separation structure 120 may be coplanar with an upper surface of the upper insulating layer 110.

The substrate processing method and the method of manufacturing the semiconductor device using the same according to some implementations may include the measuring of the plasma, and the measuring of the plasma may include measuring plasma emission intensity, and compensating for the decreased transmittance due to the by-products. Accordingly, the chemical species density to be calculated by excluding electron density and clogging effects from the plasma emission intensity. The chemical species density may change at an interface of layers containing different materials during the etching process. Accordingly, the substrate processing method and the method of manufacturing the semiconductor device using the same may provide the precise etch end-point.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A substrate processing method, the method comprising:
preparing a substrate in a substrate processing apparatus including a view port;
processing the substrate using plasma; and
measuring the plasma using a measurement device connected to the view port,
wherein the measurement device includes a first measurement unit and a second measurement unit, and
wherein measuring of the plasma includes
measuring plasma emission intensity,
compensating for electron density in the plasma using the second measurement unit, and
compensating for decreased transmittance of the view port using the first measurement unit.

2. The method of claim 1, wherein the first measurement unit includes a light transmission device, a spectroscope, and an external light source, and
wherein the external light source includes a xenon lamp.

3. The method of claim 1, wherein the second measurement unit includes an antenna, a duplex, a receiver, and a transmitter.

4. The method of claim 1, wherein the substrate processing apparatus includes a reflector facing the view port.

5. The method of claim 4, wherein the reflector includes silicon and yttrium, and
wherein the reflector has a diameter of 1 mm to 2 mm.

6. A substrate processing method, the method comprising:
preparing a substrate in a substrate processing apparatus including a view port;
processing the substrate using plasma; and
measuring the plasma using a measurement device connected to the view port,
wherein measuring of the plasma includes
measuring plasma emission intensity,
compensating for electron density in the plasma, and
compensating for decreased transmittance of the view port, and
wherein the substrate processing apparatus includes a reflector facing the view port.

7. The method of claim 6, wherein compensating for the electron density includes measuring the electron density in the plasma and excluding the electron density from the plasma emission intensity.

8. The method of claim 7,
wherein the measurement device includes a duplexer, a transmitter, and a receiver,
wherein measuring of the electron density includes using interference between a first electromagnetic wave transmitted from the transmitter and a second electromagnetic wave received from the receiver.

9. The method of claim 8, wherein the second electromagnetic wave is the same as the first electromagnetic wave that passes through the plasma and is reflected by the reflector.

10. The method of claim 8, wherein the transmitter generates microwaves having a frequency of 1 GHz to 100 GHz.

11. The method of claim 6,
wherein the measurement device includes a light transmittance device, a spectrometer, and an external light source, and
wherein compensating for the decrease in transmittance of the view port includes comparing the plasma emission intensity in response to blinking the external light source.

12. The method of claim 11, wherein a measurement wavelength range of the spectrometer is 200 nm to 1000 nm.

13. The method of claim 6, wherein processing of the substrate and measuring of the plasma are performed simultaneously.

14. The method of claim 6, wherein the substrate processing apparatus includes:
an electrostatic chuck on which the substrate is placed;
a shower head on the electrostatic chuck and connected to a gas supplier; and
a power generator connected to the electrostatic chuck, and
wherein processing the substrate includes etching a portion of the substrate using the plasma.

15. The method of claim 14, wherein the measurement device includes:
a first measurement unit including a light transmission device, a spectrometer, and an external light source;
a second measurement unit including an antenna, a duplexer, a receiver, and a transmitter; and
a controller connected to the first measurement unit and the second measurement unit, and
wherein the controller is configured to control the gas supplier and the power generator.

16. A substrate processing method, the method comprising:
forming a mold structure on a substrate;
forming a plurality of channel holes penetrating the mold structure using plasma; and
measuring the plasma using a measurement device connected to a view port, and
wherein measuring of the plasma includes:
measuring plasma emission intensity;
compensating for electron density in the plasma; and
compensating for decreased transmittance of the view port.

17. The method of claim 16, wherein the measurement device includes:
a first measurement unit including a light transmission device, a spectroscope, and an external light source; and
a second measurement unit including an antenna, a duplexer, a receiver, and a transmitter.

18. The method of claim 17,
wherein compensating for the electron density includes measuring the electron density in the plasma and excluding the electron density from the plasma emission intensity, and
wherein compensating for the decreased transmittance of the view port includes blinking the external light source and comparing the plasma emission intensity.

19. The method of claim 16,
wherein forming the plurality of channel holes includes exposing a portion of the substrate, and
wherein an upper surface of the substrate is positioned at the same level as bottom surfaces of the plurality of channel holes.

20. The method of claim 16, further comprising forming vertical structures in each of the plurality of channel holes, respectively,
wherein the vertical structures include a vertical insulating pattern, a vertical semiconductor pattern, a data storage pattern, and a conductive pad.
